(19) United States
(12) Patent Application Publication
(10) Pub. No.: US 2022/0146948 A1
(43) Pub. Date: May 12, 2022

(54) ELECTROSTATIC CLAMP FOR A LITHOGRAPHIC APPARATUS

(71) Applicant: ASML Holding N.V., Veldhoven (NL)

(72) Inventors: Hari KRISHNAN, Norwalk, CT (US); Joseph Harry LYONS, Wilton, CT (US); Eric Justin MONKMAN, Fairfield, CT (US); Victor Antonio PEREZ-FALCON, Bridgeport, CT (US)

(73) Assignee: ASML Holding N.V., Veldhoven (NL)

(21) Appl. No.: 17/438,021

(22) PCT Filed: Mar. 6, 2020
(86) PCT No.: PCT/EP2020/055957

§ 371 Date: Sep. 10, 2021

Related U.S. Application Data
(60) Provisional application No. 62/817,671, filed on Mar. 13, 2019.

(51) Int. Cl. G03F 7/20; H01L 21/683

(52) U.S. Cl. CPC G03F 7/70708; H01L 21/6833

(57) ABSTRACT

An electrostatic clamp for supporting a substrate includes a substrate region, an electrode region at an edge of the substrate region, a support layer, an electrically conductive layer, a contact layer, and an electrode. The support layer has a body having first and second surfaces that are substantially parallel to each other and disposed on opposite sides of the body. A through-hole is disposed in the electrode region and provides access between the first and second surfaces. The electrically conductive layer is disposed on the second surface of the support layer. The contact layer disposed on the electrically conductive layer. The contact layer is uninterrupted in the electrode region and comprises burls in the substrate region. The burls contact the substrate when the electrostatic clamp is supporting the substrate. The electrode is disposed in the through-hole and is electrically coupled to the electrically conductive layer.

### CROSS-REFERENCE TO RELATED APPLICATIONS

This application claims priority of U.S. Provisional Patent Application No. 62/817,671, which was filed on Mar. 13, 2019, and which is incorporated herein in its entirety by reference.

### FIELD

The present disclosure relates to electrostatic clamps for reticles and substrates in lithography apparatuses and systems.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern of a patterning device (e.g., a mask, a reticle) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Clamps may be used in lithographic apparatuses and systems to hold a reticle or wafer (e.g., a substrate) in place. However, the vacuum requirements within lithographic apparatuses and systems tend to favor the use of electrostatic clamps, which use Coulomb potential to attract and affix an object in place. The voltage connection that supplies the Coulomb potential is a complex structure that can introduce premature failure of the clamp. There is a need to reduce damage to the clamp in a reliable, uniform, and efficient manner.

### SUMMARY

In some embodiments, an electrostatic clamp for supporting a substrate includes a substrate region, an electrode region at an edge of the substrate region, a support layer, an electrically conductive layer, a contact layer, and an electrode. The support layer has a body having first and second surfaces. The first and second surfaces are disposed on opposite sides of the body and are substantially parallel to each other. The through-hole is disposed in the electrode region. The through-hole is configured to provide access between the first and second surfaces. The electrically conductive layer is disposed on the second surface of the support layer. The contact layer disposed on the electrically conductive layer. The contact layer is uninterrupted in the electrode region and comprises burls in the substrate region. The burls are configured to contact the substrate when the electrostatic clamp is supporting the substrate. The electrode is disposed in the through-hole and is electrically coupled to the electrically conductive layer. In some embodiments, a width of the through-hole is smaller at the second surface than at the first surface In other embodiments, the width of the through-hole is larger at the second surface than at the first surface.

In some embodiments, an electrostatic clamp for supporting a substrate includes a substrate region, an electrode region at an edge of the substrate region, a support layer, an electrically conductive layer, a contact layer, and an electrode. The support layer has a body having first and second surfaces. The first and second surfaces are disposed on opposite sides of the body and are substantially parallel to each other. The through-hole is disposed in the electrode region. The through-hole is configured to provide access between the first and second surfaces. The electrically conductive layer is disposed on the second surface of the support layer. The contact layer disposed on the electrically conductive layer. The contact layer is uninterrupted in the electrode region and comprises burls in the substrate region. The burls are configured to contact the substrate when the electrostatic clamp is supporting the substrate. The electrode is disposed in the through-hole and is electrically coupled to the electrically conductive layer. In some embodiments, the electrode can comprise a spring or a flexure.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention. Embodiments of the invention will now be described, by way of example only, with reference to the accompanying schematic drawings, in which:

FIG. 1 shows a schematic illustration of a lithographic apparatus, according to some embodiments.

FIG. 2 shows a perspective schematic illustration of a reticle stage, according to some embodiments.

FIG. 3 shows a top plan view of the reticle stage of FIG. 2.

FIG. 4 shows a perspective schematic illustration of a reticle exchange apparatus, according to some embodiments.

FIG. 5 shows a partial cross-sectional view of the reticle exchange apparatus of FIG. 4.

FIG. 6A shows a partial schematic illustration of a reticle exchange apparatus in an approach configuration, according to some embodiments.

FIG. 6B shows a partial schematic illustration of a reticle exchange apparatus in a first contact configuration, according to some embodiments.

FIG. 6C shows a partial schematic illustration of a reticle exchange apparatus in a full contact configuration, according to some embodiments.

FIG. 7 shows a perspective schematic illustration of an electrostatic clamp, according to some embodiments.

FIGS. 8-14 show schematic cross-sectional views of electrostatic clamps, according to some embodiments.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., ±10%, ±20%, or ±30% of the value).

Embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions may be described herein as performing certain actions. However, it should be appreciated that such descriptions are merely for convenience and that such actions in fact result from computing devices, processors, controllers, or other devices executing the firmware, software, routines, instructions, etc., and in doing that may cause actuators or other devices to interact with the physical world.

Before describing such embodiments in more detail, however, it is instructive to present an example environment in which embodiments of the present disclosure may be implemented.

Exemplary Lithographic System

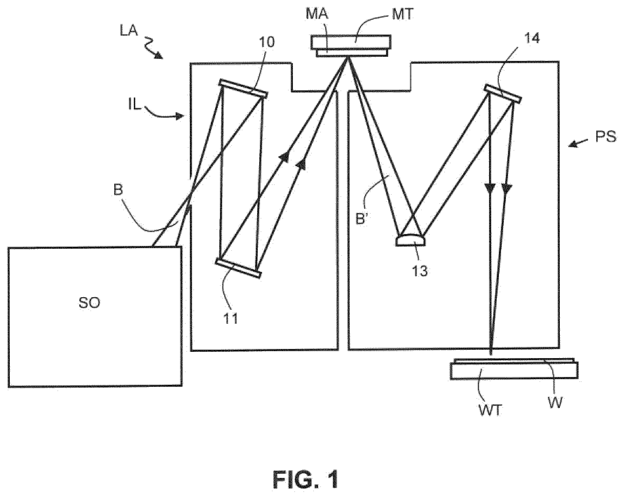

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS, and a substrate table WT configured to support a substrate W.

The illumination system IL is configured to condition the EUV radiation beam B before the EUV radiation beam B is incident upon the patterning device MA. Thereto, the illumination system IL can include a faceted field mirror device 10 and a faceted pupil mirror device 11. The faceted field mirror device 10 and faceted pupil mirror device 11 together provide the EUV radiation beam B with a desired cross-sectional shape and a desired intensity distribution. The illumination system IL can include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS can comprise a plurality of mirrors 13, 14 which are configured to project the patterned EUV radiation beam B′ onto the substrate W held by the substrate table WT. The projection system PS can apply a reduction factor to the patterned EUV radiation beam B′, thus forming an image with features that are smaller than corresponding features on the patterning device MA. For example, a reduction factor of 4 or 8 can be applied. Although the projection system PS is illustrated as having only two mirrors 13, 14 in FIG. 1, the projection system PS can include a different number of mirrors (e.g., six or eight mirrors).

The substrate W can include previously formed patterns. Where this is the case, the lithographic apparatus LA aligns the image, formed by the patterned EUV radiation beam B′, with a pattern previously formed on the substrate W.

A relative vacuum, i.e., a small amount of gas (e.g., hydrogen) at a pressure well below atmospheric pressure, can be provided in the radiation source SO, in the illumination system IL, and/or in the projection system PS.

The radiation source SO can be a laser produced plasma (LPP) source, a discharge produced plasma (DPP) source, a free electron laser (FEL), or any other radiation source that is capable of generating EUV radiation.

Exemplary Reticle Stage

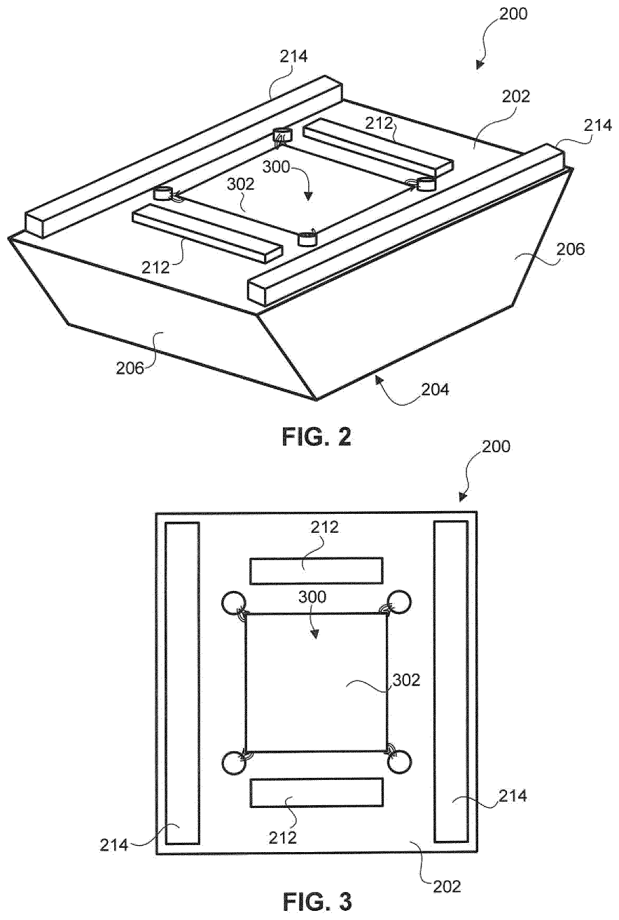

FIGS. 2 and 3 show schematic illustrations of an exemplary reticle stage 200, according to some embodiments. Reticle stage 200 can include top stage surface 202, bottom stage surface 204, side stage surfaces 206, and clamp 300. In some embodiments, reticle stage 200 with clamp 300 can be implemented in lithographic apparatus LA. For example, reticle stage 200 can be support structure MT in lithographic apparatus LA. In some embodiments, clamp 300 can be disposed on top stage surface 202. For example, as shown in FIG. 2, clamp 300 can be disposed at a center of top stage surface 202 with clamp frontside 302 facing perpendicularly away from top stage surface 202.

In some lithographic apparatuses, for example, lithographic apparatus LA, a reticle stage 200 with a clamp 300 can be used to hold and position a reticle 408 for scanning or patterning operations. In one example, the reticle stage 200 can require powerful drives, large balance masses, and heavy frames to support it. In one example, the reticle stage 200 can have a large inertia and can weigh over 500 kg to propel and position a reticle 408 weighing about 0.5 kg. To accomplish reciprocating motions of the reticle 408, which are typically found in lithographic scanning or patterning operations, accelerating and decelerating forces can be provided by linear motors that drive the reticle stage 200.

In some embodiments, as shown in FIGS. 2 and 3, reticle stage 200 can include first encoder 212 and second encoder 214 for positioning operations. For example, first and second encoders 212, 214 can be interferometers. First encoder 212 can be attached along a first direction, for example, a transverse direction (i.e., X-direction) of reticle stage 200. And second encoder 214 can be attached along a second direction, for example, a longitudinal direction (i.e., Y-direction) of reticle stage 200. In some embodiments, as shown in FIGS. 2 and 3, first encoder 212 can be orthogonal to second encoder 214.

As shown in FIGS. 2 and 3, reticle stage 200 can include clamp 300. Clamp 300 is configured to hold reticle 408 in a fixed plane on reticle stage 200. Clamp 300 includes clamp frontside 302 and can be disposed on top stage surface 202. In some embodiments, clamp 300 can use mechanical, vacuum, electrostatic, or other suitable clamping techniques to hold and secure an object. In some embodiments, clamp 300 can be an electrostatic clamp, which can be configured to electrostatically clamp (i.e., hold) an object, for example, reticle 408 in a vacuum environment. Due to the requirement to perform EUV in a vacuum environment, vacuum clamps cannot be used to clamp a mask or reticle and instead electrostatic clamps can be used. For example, clamp 300 can include an electrode, a resistive layer on the electrode, a dielectric layer on the resistive layer, and burls projecting from the dielectric layer. In use, a voltage can be applied to clamp 300, for example, several kV (e.g., high-voltage). And current can flow through the resistive layer, such that the voltage at an upper surface of the resistive layer will substantially be the same as the voltage of the electrode and generate an electric field. Also, a Coulomb force, attractive force between electrically opposite charged particles, will attract an object to clamp 300 and hold the object in place. In some embodiments, clamp 300 can be a rigid material, for example, a metal, a dielectric, a ceramic, or a combination thereof.

Exemplary Reticle Exchange Apparatus

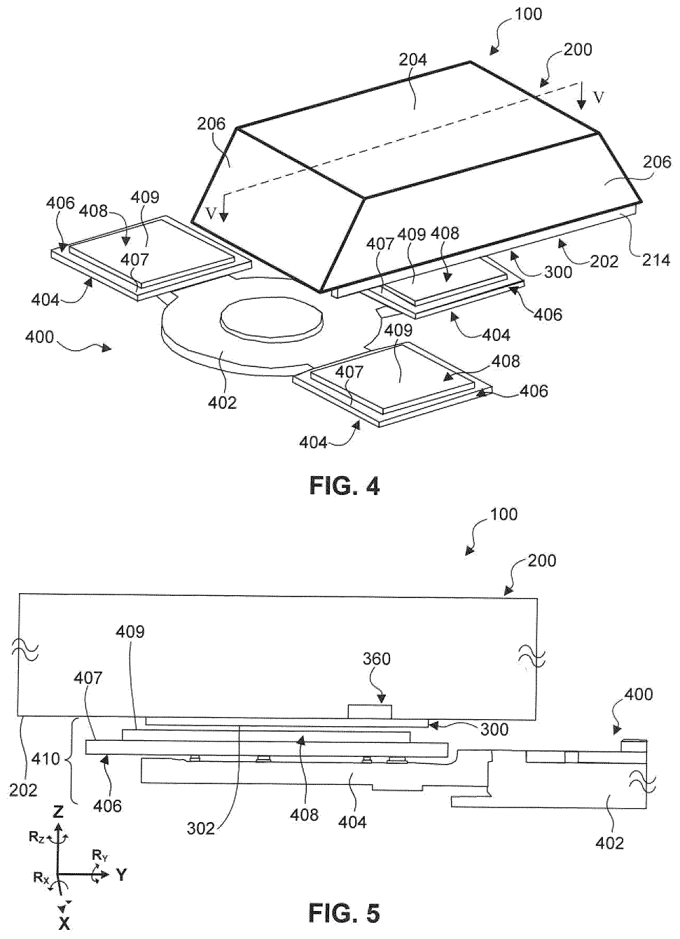

FIGS. 4 through 6 show schematic illustrations of an exemplary reticle exchange apparatus 100, according to some embodiments. Reticle exchange apparatus 100 can be configured to minimize reticle exchange time, particle generation, and contact forces or stresses from clamp 300 and/or reticle 408 to reduce damage to clamp 300 and reticle 408 and increase overall throughput in a reticle exchange process, for example, in a lithographic apparatus LA.

As shown in FIGS. 4 and 5, reticle exchange apparatus 100 can include reticle stage 200, clamp 300, and in-vacuum robot 400. In-vacuum robot 400 can include reticle handler 402.

In some embodiments, reticle handler 402 can be a rapid exchange device (RED), which is configured to efficiently rotate and minimize reticle exchange time. For example, reticle handler 402 can save time by moving multiple reticles from one position to another substantially simultaneously, instead of serially.

In some embodiments, as shown in FIG. 4, reticle handler 402 can include one or more reticle handler arms 404. Reticle handler arm 404 can include reticle baseplate 406. Reticle baseplate 406 can be configured to hold an object, for example, reticle 408.

In some embodiments, reticle baseplate 406 can be an extreme ultraviolet inner pod (EIP) for a reticle. In some embodiment, reticle baseplate 406 includes reticle baseplate frontside 407, and reticle 408 includes reticle backside 409.

In some embodiments, as shown in FIGS. 4 and 5, reticle baseplate 406 can hold reticle 408 such that reticle baseplate frontside 407 and reticle backside 409 each face top stage surface 202 and clamp frontside 302. For example, reticle baseplate frontside 407 and reticle backside 409 can be facing perpendicularly away from top stage surface 202 and clamp frontside 302.

As shown in FIG. 5, reticle exchange apparatus 100 can include reticle exchange area 410, which is the cross-sectional area between clamp 300, reticle 408, reticle baseplate 406, and reticle handler arm 404 during a reticle exchange process.

In some embodiments, as shown in FIG. 4, reticle handler arms 404 can be arranged symmetrically about reticle handler 402. For example, reticle handler arms 404 can be spaced from each other by about 90 degrees, 120 degrees, or 180 degrees. In some embodiments, reticle handler arms 404 can be arranged asymmetrically about reticle handler 402. For example, two reticle handler arms 404 can be spaced from each other by about 135 degrees, while another two reticle handler arms 404 can be spaced from each other by about 90 degrees.

In one example, during a reticle exchange process, reticle handler arm 404 of reticle handler 402 positions reticle 408 on reticle baseplate 406 towards clamp 300 in reticle exchange area 410. As described above, a reticle handoff from reticle handler 402 to clamp 300 includes an unknown reticle position offset, which includes a reticle vertical distance offset (i.e., Z-direction offset) and a reticle tilt offset (i.e., R_{X} offset and R_{Y} offset). The terms “vertical/vertically” may be used herein to refer to directions that are substantially perpendicular to the major opposing surfaces of a substrate (e.g., vertical with respect to a first surface of an electrostatic clamp). Tilt or excessive non-alignment between clamp 300 and reticle 408 can be a source of particle generation and can damage reticle 408 or clamp 300 over time. Reticle backside 409 and clamp frontside 302 need to be in optimal coplanar alignment for a final handoff. Despite calibration, variations still exist due to reticle mechanical and positioning tolerances, which can lead to high corner impacts and unpredictable first contact points between clamp 300 and reticle 408.

In one example, the reticle exchange process can involve lowering reticle stage 200 with clamp 300, which starts far away from reticle handler 402, as close to reticle 408 as possible until clamp 300 contacts reticle 408 to account for all possible offsets and/or tilts. During a reticle exchange process, reticle stage 200 with clamp 300 can be adjusted in a multi-stage movement.

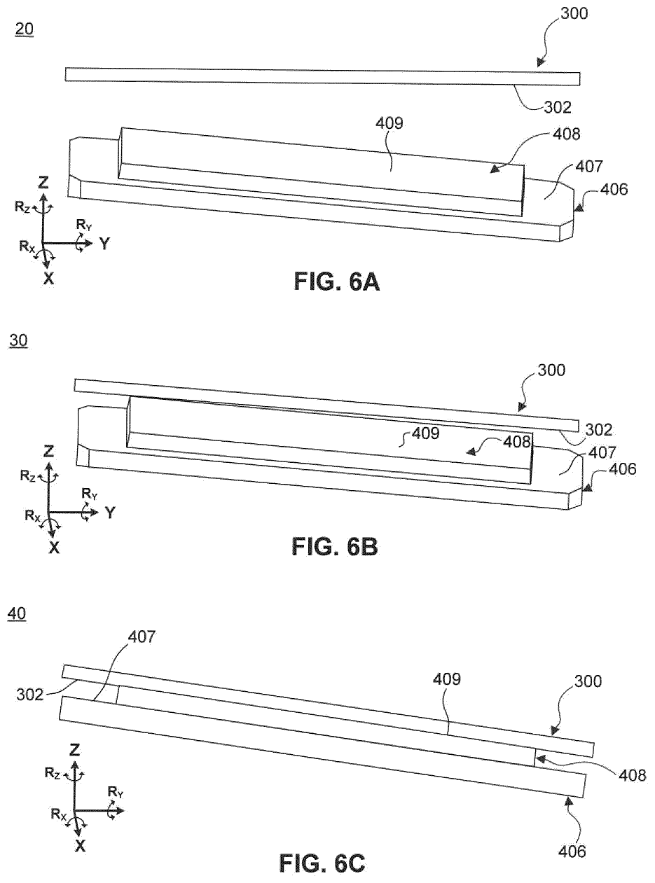

As shown in FIGS. 6A through 6C, reticle exchange apparatus 100 can include clamp 300, reticle 408, and reticle baseplate 406. The multi-stage movement can occur in four stages: (1) approach; (2) first contact; (3) full contact; and (4) voltage applied to clamp.

First, as shown in FIG. 6A, reticle exchange apparatus 100 can be in an approach configuration 20 and clamp 300 can be adjusted in a substantially vertical direction (i.e., Z-direction) toward reticle backside 409. In approach configuration 20, clamp 300 is turned off (i.e., no applied voltage) and reticle handler 402 deactivates the vertical direction (i.e., Z-direction) and tilt (i.e., R_{X} and R_{Y}, rotation about X-direction and rotation about Y-direction, respectively) servo motors of reticle handler arm 404 in reticle exchange area 410. The motors (i.e., Z, R_{X}, and R_{Y}) brake and rotation about Z-direction (i.e., R_{Z}) activates.

Second, as shown in FIG. 6B, reticle exchange apparatus 100 can be in a first contact configuration 30 and clamp 300 can be adjusted in a substantially vertical direction (i.e., Z-direction) toward reticle backside 409 until clamp 300 makes contact with reticle backside 409. In first contact configuration 30, clamp 300 is turned off and clamp 300 makes contact with reticle backside 409, for example, a corner of reticle 408, and then rotates or tilts about the contact (i.e., R_{X} and R_{Y}).

Third, as shown in FIG. 6C, reticle exchange apparatus 100 can be in a full contact configuration 40 and clamp 300 can be rotationally adjusted about the contact (i.e., R_{X} and R_{Y}) toward reticle backside 409 until clamp 300 makes full contact with reticle backside 409. In full contact configuration 40, clamp 300 is turned off and clamp 300 makes full contact with reticle backside 409, for example, all four corners of reticle 408, and is coplanar with reticle backside 409.

In some embodiments, in full contact configuration 40, clamp 300 makes contact with all four corners of reticle 408 and continues to move in a substantially vertical direction (i.e., Z-direction) until a mechanical force of at least 5 N is achieved.

Fourth, with clamp frontside 302 and reticle backside 409 aligned and coplanar, clamp 300 is turned on (i.e., a voltage is applied to clamp 300) and reticle 408 is held in a fixed plane on clamp 300.

In some embodiments, as shown in FIG. 5, reticle exchange apparatus 100 can include clamp controller 360. Clamp controller 360 can be coupled to clamp 300 and be configured to control a position of clamp 300. For example, clamp controller 360 can be configured to control reticle stage 200 to allow compliant movement of clamp 300. In some embodiments, clamp controller 360 can be coupled to servo motors or servo actuators (i.e., X-direction, Y-direction, Z-direction, R_{X}, R_{Y}, R_{Z}) of reticle stage 200 and/or clamp 300. For example, clamp controller 360 can control translations of reticle stage 200 with clamp 300 along an x-axis, y-axis, and z-axis (i.e., X-direction, Y-direction, Z-direction) and rotations about the x-axis, y-axis, and z-axis (i.e., R_{X}, R_{Y}, R_{Z}), where the x-axis, y-axis, and z-axis are orthogonal coordinates.

Exemplary Electrostatic Clamps

In the context of electrostatic clamp operations and functions, the term “substrate” may be used herein to refer to flat objects that require frequent clamping and release in a lithographic apparatus or system. Therefore, the term “substrate” can also refer to a patterning device (e.g., a reticle) in the context of electrostatic clamp operations and functions. For example, an electrostatic clamp can be configured to support a substrate, wherein the substrate is a reticle or a semiconductor wafer, or the like.

Electrostatic clamps provide a rigid and stable hold on substrates by employing a Coulomb potential. The potential difference between the clamp and substrate generates an attractive force, causing the substrate to become rigidly secured to the electrostatic clamp. The structure of an electrostatic clamp typically comprises a conductive sheet or layer that is sandwiched between two insulators. In order to gain electrical access to the conductive layer and supply it the required voltage, bores are made in the insulating layers and electrodes are inserted to make contact with the conductive layer. The region around these electrode bores can become a premature point of failure due to, for example, mismatch of the coefficient of thermal expansion (CTE) of the various materials that make up the high-voltage connection architecture. Therefore, in some embodiments, materials exhibiting ultra-low expansion (ULE) behavior is used.

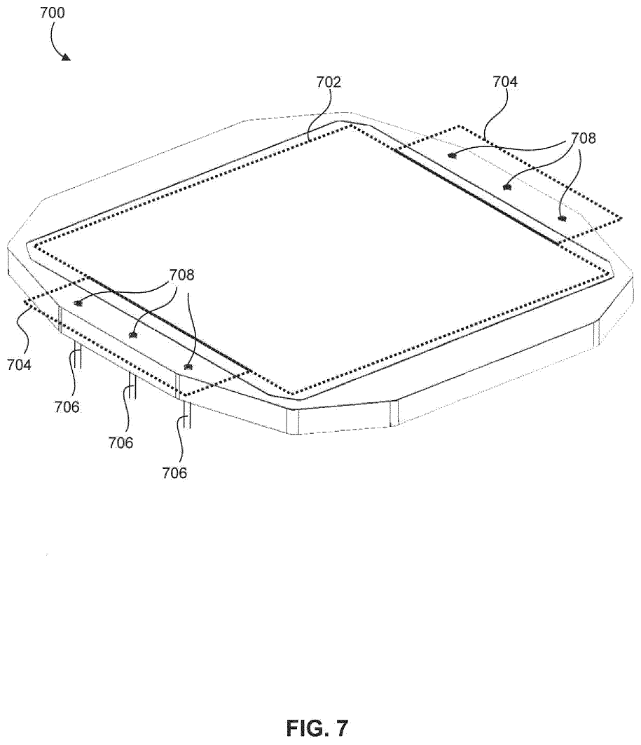

FIG. 7 shows a perspective schematic illustration of an electrostatic clamp 700, according to some embodiments. For ease of discussion, FIG. 7 shows the “frontside” of electrostatic clamp 700 (i.e., the side that makes contact with a substrate) facing up. In some embodiments, electrostatic clamp 700 is arranged as having a substrate region 702 and at least one electrode region 704. The extent of substrate region 702 and electrode region 704 are denoted approximately by correspondingly labeled dashed rectangles. Electrode region 704 comprises at least one electrode 706. Electrode region 704 comprises a cap 708 for each electrode 706. It is to be appreciated that electrostatic clamp 700 comprises an electrically conductive layer that is disposed within electrostatic clamp 700 and extends fully or partially throughout substrate region 702 and electrode region 704. In some embodiments, the electrically conductive layer is contiguous or non-contiguous (e.g., a mesh). The electrically conductive layer is not shown in FIG. 7 due to limitations of perspective, but will be shown in other cross-sectional drawings.

In some embodiments, electrode region 704 is disposed at an edge of, or adjacent to, substrate region 702. electrode 706 is inserted into electrostatic clamp 700 through a through-hole that has been bored into electrostatic clamp 700 in electrode region 704. Electrode 706 is electrically coupled to the electrically conductive layer within electrostatic clamp 700. It is desirable to coat the frontside of electrode region 704 with a grounding chrome coating, as this coating will provide the reference potential for the high-voltage supplied to the electrically conductive layer within electrostatic clamp 700. However, the difference between materials and geometries at the through-hole (e.g., insulator, electrical conductors) can cause the different materials to separate, particularly on portions of the frontside surrounding the through-hole. This can cause the chrome coating to lose electrical connectivity (i.e., loss of clamping force) and/or generate debris within the clean environment of a lithographic apparatus or system. Therefore, in some embodiments, cap 708 is disposed on the through-hole on the frontside. Cap 708 is affixed in place using a bonding agent (e.g., epoxy, ULE epoxy). The grounding chrome coating mentioned earlier is applied over cap 708.

In some embodiments, substrate region 702 comprises microscopic bulges (not shown), or burls, that are configured to contact a substrate when electrostatic clamp 700 supports the substrate. Electrode 706 is configured to receive a voltage from a voltage source and transmit the voltage to the electrically conductive layer within electrostatic clamp 700. When electrostatic clamp 700 supports a grounded substrate, the voltage applied to the electrically conductive layer causes a Coulomb force to attract the substrate onto electrostatic clamp 700. This mechanism allows electrostatic clamps to firmly hold a substrate.

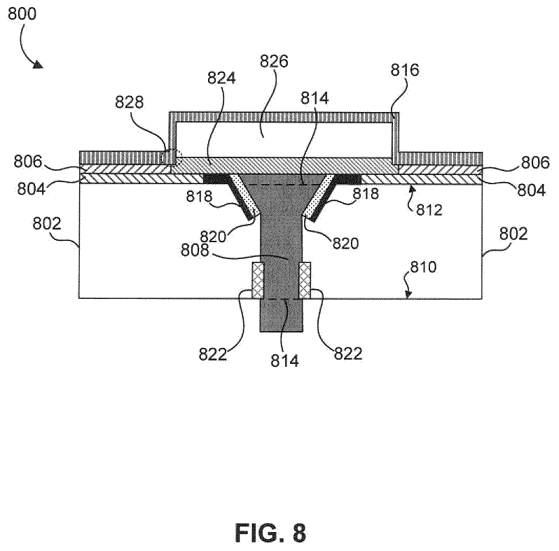

FIG. 8 shows a schematic cross-sectional view of an electrostatic clamp 800, according to some embodiments. The region of electrostatic clamp 800 shown in FIG. 8 is one that includes an electrode (e.g., an electrode region). It is to be appreciated that electrostatic clamp 800 also includes a substrate region—not shown here due to limitations of cross-sectional drawings—having structures and functions as described previously for substrate region 702 (FIG. 7). In some embodiments, electrostatic clamp 800 comprises a support layer 802, an electrically conductive layer 804, a contact layer 806, and an electrode 808. Support layer 802 comprises a body, the body comprising a first surface 810 and a second surface 812. Support layer 802 further comprises at least one through-hole 814. Electrostatic clamp 800 further comprises a second electrically conductive layer 816 (e.g., chrome). In some embodiments, a sidewall of through-hole 814 comprises an electrically conductive coating 818 (e.g., chrome). In some embodiments, through-hole 814 is filled with a conductive bonding agent 820 (e.g., electrically conductive epoxy—in lieu of or in addition to electrically conductive coating 818—in the space not occupied by electrode 808. Electrostatic clamp 800 further comprises a bonding agent 822, a bonding agent 824, a cap 826, and a positive fillet 828.

In some embodiments, support layer 802 and contact layer 806 comprise ULE materials. In some embodiments, support layer 802 comprises the same ULE material as contact layer 806. In some embodiments, support layer 802 comprises a different ULE material from contact layer 806, but the CTE of the ULE material of support layer 802 is substantially similar to the CTE of the ULE material of contact layer 806. The matching of CTEs improves the robustness of electrostatic clamp 800 against failures related to cycles of heating and cooling (i.e., thermal cycling). In some embodiments, support layer 802 can comprise two sublayers (not shown) of ULE material. Designing support layer 802 as two fused sublayers allows support layer 802 to be fabricated as separate parts. Consequently, this allows the separate sublayers to be processed differently before they are fused together, using a bonding agent, to construct support layer 802. There are certain fabrication procedures (e.g., milling, perforation, etching, polishing, among others) that can benefit from being applied separately to a sublayer of support layer 802. Features of the ULE materials having sublayers can also be applied to other embodiments of the present disclosure.

In some embodiments, first surface 810 and second surface 812 are disposed on opposite sides of the body of support layer 802. First surface 810 and second surface 812 are substantially parallel to each other. Electrically conductive layer 804 is disposed on second surface 812 of support layer 802. Contact layer 806 is disposed on electrically conductive layer 804. Second electrically conductive layer 816 is disposed on contact layer 806 and cap 826. Electrode 808 is disposed in through-hole 814.

In some embodiments, through-hole 814 is configured to provide access between first surface 810 and second surface 812. Particularly, through-hole 814 allows one to gain electrical access to electrically conductive layer 804 by coming in from first surface 810 (e.g., using electrode 808). In some embodiments, the width of through-hole 814 is larger at second surface 812 than at first surface 810. By having this particular width configuration, some fabrication processes can be made easier by allowing the insertion of electrode 808 into through-hole 814 from the side of second surface 812. In this scenario, the portion of electrode 808 disposed in through-hole 814 has a width that is larger near second surface 812 than at first surface 810. By matching a shape of electrode 808 to a shape of through-hole 814, a snug fit of electrode 808 can be achieved for improved stability. For further improving stability, electrode 808 can be affixed to support layer 802 using bonding agent 822.

In some embodiments, electrically conductive coating 818 is electrically coupled to electrically conductive layer 804 and electrode 808. In other words, electrically conductive layer 804 and electrode 808 are electrically coupled through electrically conductive coating 818. In embodiments that include conductive bonding agent 820, electrically conductive layer 804 and electrode 808 are electrically coupled through conductive bonding agent 820 and/or electrically conductive coating 818. In some embodiments, second electrically conductive layer 816 is configured to provide an electrical ground.

It was mentioned earlier that the difference between materials and geometries at a through-hole can cause the different materials to separate, particularly on portions surrounding the through-hole on the frontside of an electrostatic clamp. To mitigate this undesirable effect, in some embodiments, cap 826 is disposed on contact layer 806 so as to cover through-hole 814. The contiguity of contact layer 806 is broken due to a hole that has been manufactured through contact layer 806 in order to, for example, deposit electrically conductive coating 818 or manufacture through-hole 814. Bonding agent 824 is disposed in said hole of contact layer 806. Cap 826 contacts bonding agent 824, affixing cap 826 in place. Positive fillet 828 provides a contiguous transition between contact layer 806 and cap 826. Such a continuous transition is important, for example, for allowing a contiguous deposition of second electrically conductive layer 816.

Embodiments based on FIG. 8 provide a “capping” method to address issues of material separation and ensuing premature failure of electrostatic clamps. However, the capping method presents a number of undesirable qualities. For example, the presence of the glass cap interrupts the “flatness” of the frontside of an electrostatic clamp, making the electrostatic clamp more difficult to clean. In another example, positive fillet 828 is underfilled, which can cause second electrically conductive layer 816 to be discontinuous, leading to field leakage. In contrast, overfilling of positive fillet 828 can lead to inconsistent deposition of second electrically conductive layer 816 and the coating can flake off. Further embodiments of the present disclosure provide electrostatic clamp structures and methods that minimize or eliminate failures due to capping electrodes.

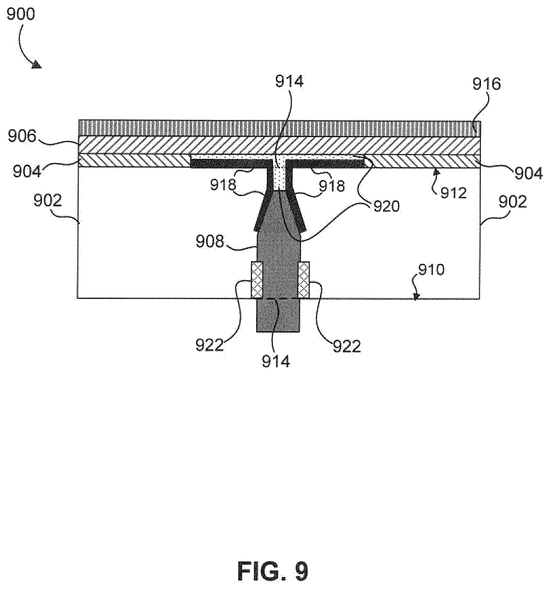

FIG. 9 shows a schematic cross-sectional view of an electrostatic clamp 900, according to some embodiments. The region of electrostatic clamp 900 shown in FIG. 9 is one that includes an electrode (e.g., an electrode region). It is to be appreciated that electrostatic clamp 900 also includes a substrate region—not shown here due to limitations of cross-sectional drawings—having structures and functions as described previously for substrate region 702 (FIG. 7). In some embodiments, electrostatic clamp 900 comprises a support layer 902, an electrically conductive layer 904, a contact layer 906, and an electrode 908. Support layer 902 comprises a body, the body comprising a first surface 910 and a second surface 912. Support layer 902 further comprises at least one through-hole 914. Contact layer 906 further comprises a second electrically conductive layer 916. In some embodiments, a sidewall of through-hole 914 comprises an electrically conductive coating 918 (e.g., chrome coating). In some embodiments, through-hole 914 is filled with a conductive bonding agent 920—in lieu of or in addition to electrically conductive coating 918—in the space not occupied by electrode 908. Electrostatic clamp 900 further comprises a bonding agent 922.

In some embodiments, support layer 902 and contact layer 906 comprise materials that exhibits ultra-low expansion (ULE) with respect to temperature changes. In some embodiments, support layer 902 comprises the same ULE material as contact layer 906. In some embodiments, support layer 902 comprises a different ULE material from contact layer 906, but the coefficient of thermal expansion (CTE) of the ULE material of support layer 902 is substantially similar to the CTE of the ULE material of contact layer 906. The matching of CTEs improves the robustness of electrostatic clamp 900 against failures related to thermal cycling. In some embodiments, support layer 902 can comprise two sub-layers (not shown) of ULE material. Designing support layer 902 as two fused sub-layers allows support layer 902 to be fabricated as separate parts, for reasons as described earlier in reference to FIG. 8.

In some embodiments, first surface 910 and second surface 912 are disposed on opposite sides of the body of support layer 902. First surface 910 and second surface 912 are substantially parallel to each other. Electrically conductive layer 904 is disposed on second surface 912 of support layer 902. Contact layer 906 is disposed on electrically conductive layer 904. Second electrically conductive layer 916 is disposed on contact layer 906. Electrode 908 is disposed in through-hole 914.

In some embodiments, through-hole 914 is configured to provide access between first surface 910 and second surface 912. Particularly, through-hole 914 allows one to gain electrical access to electrically conductive layer 904 by coming in from first surface 910 (e.g., using electrode 908). The width of through-hole 914 is smaller at second surface 912 than at first surface 910. In the electrode region, contact layer 906 is contiguous, or uninterrupted. This design exhibits several desirable qualities. For example, it reduces the surface area of pressure exerted by bonding agents on contact layer 906, removing the need for a cap. Another quality is that electrode 908 can be inserted from first surface 910 without damaging or altering contact layer 906, which allows rework-ability of the high-voltage connection.

In some embodiments, electrically conductive layer 904 and electrode 908 are electrically coupled through electrically conductive coating 918. In embodiments that include conductive bonding agent 920, electrically conductive layer 904 and electrode 908 are electrically coupled through electrically conductive material 920 and/or electrically conductive coating 918. In some embodiments, second electrically conductive layer 916 is configured to provide an electrical ground.

In some embodiments, the portion of electrode 908 disposed in through-hole 914 has a width that is smaller away from first surface 910, and toward second surface 912, than at first surface 910. By matching a shape of electrode 908 to a shape of through-hole 914, a snug fit of electrode 908 can be achieved for improved stability. For further improving stability, electrode 908 can be affixed to support layer 902 using bonding agent 922.

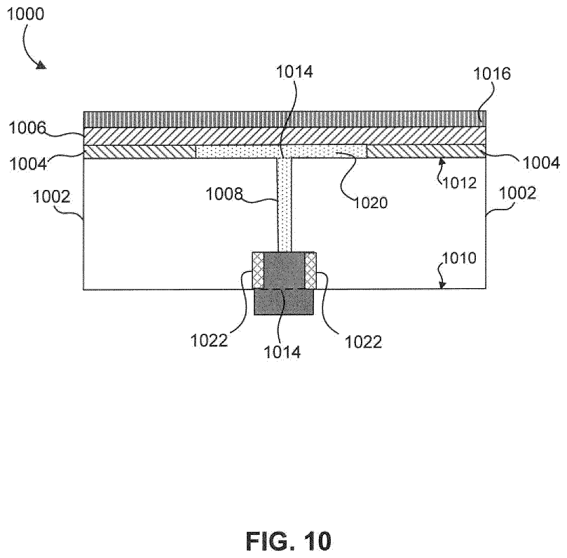

FIG. 10 shows a schematic cross-sectional view of an electrostatic clamp 1000, according to some embodiments. The region of electrostatic clamp 1000 shown in FIG. 10 is one that includes an electrode (e.g., an electrode region). It is to be appreciated that electrostatic clamp 1000 also includes a substrate region—not shown here due to limitations of cross-sectional drawings—having structures and functions as described previously for substrate region 702 (FIG. 7). In some embodiments, electrostatic clamp 1000 comprises a support layer 1002, an electrically conductive layer 1004, a contact layer 1006, and an electrode 1008. Support layer 1002 comprises a body, the body comprising a first surface 1010 and a second surface 1012. Support layer 1002 further comprises at least one through-hole 1014. Contact layer 1006 further comprises a second electrically conductive layer 1016. In some embodiments, through-hole 1014 is filled with a conductive bonding agent 1020 in the space not occupied by electrode 1008. Electrostatic clamp 1000 further comprises a bonding agent 1022.

In some embodiments, support layer 1002 and contact layer 1006 comprise ULE materials. In some embodiments, support layer 1002 comprises the same ULE material as contact layer 1006. In some embodiments, support layer 1002 comprises a different ULE material from contact layer 1006, but the CTE of the ULE material of support layer 1002 is substantially similar to the CTE of the ULE material of contact layer 1006. The matching of CTEs improves the robustness of electrostatic clamp 1000 against failures related to thermal cycling. In some embodiments, support layer 1002 can comprise two sub-layers (not shown) of ULE material. Designing support layer 1002 as two fused sub-layers allows support layer 1002 to be fabricated as separate parts, for reasons as described earlier in reference to FIG. 8.

In some embodiments, first surface 1010 and second surface 1012 are disposed on opposite sides of the body of support layer 1002. First surface 1010 and second surface 1012 are substantially parallel to each other. Electrically conductive layer 1004 is disposed on second surface 1012 of support layer 1002. Contact layer 1006 is disposed on electrically conductive layer 1004. Second electrically conductive layer 1016 is disposed on contact layer 1006. Electrode 1008 is disposed in through-hole 1014.

In some embodiments, through-hole 1014 is configured to provide access between first surface 1010 and second surface 1012. Particularly, through-hole 1014 allows one to gain electrical access to electrically conductive layer 1004 by coming in from first surface 1010 (e.g., using electrode 1008). The width of through-hole 1014 is smaller at second surface 1012 than at first surface 1010. In the electrode region, contact layer 1006 is uninterrupted. This design further reduces the surface area of pressure exerted by bonding agents on contact layer 1006 as compared to how it was achieved in FIG. 9. Furthermore, electrode 1008 can be inserted from first surface 1010 without damaging or altering contact layer 1006, which allows rework-ability of the high-voltage connection.

In some embodiments, electrically conductive layer 1004 and electrode 1008 are electrically coupled through electrically conductive material 1020. In some embodiments, second electrically conductive layer 1016 is configured to provide an electrical ground.

In some embodiments, the portion of electrode 1008 disposed in through-hole 1014 has a width that is substantially constant. By matching a shape of electrode 1008 to a shape of through-hole 1014, a snug fit of electrode 1008 can be achieved for improved stability. For further improving stability, electrode 1008 can be affixed to support layer 1002 using bonding agent 1022.

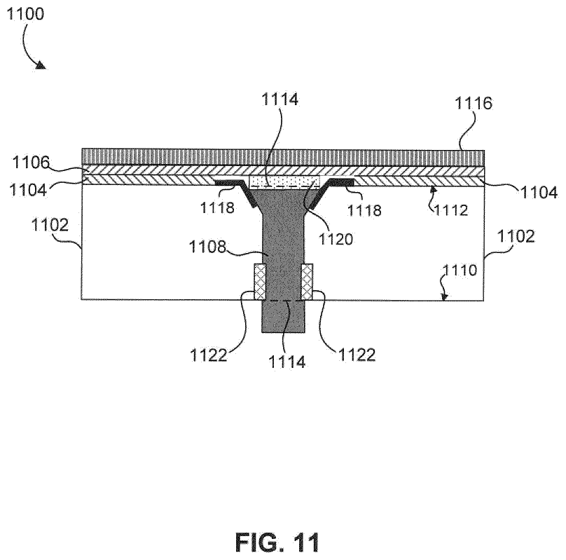

FIG. 11 shows a schematic cross-sectional view of an electrostatic clamp 1100, according to some embodiments. The region of electrostatic clamp 1100 shown in FIG. 11 is one that includes an electrode (e.g., an electrode region). It is to be appreciated that electrostatic clamp 1100 also includes a substrate region—not shown here due to limitations of cross-sectional drawings—having structures and functions as described previously for substrate region 702 (FIG. 7). In some embodiments, electrostatic clamp 1100 comprises a support layer 1102, an electrically conductive layer 1104, a contact layer 1106, and an electrode 1108. Support layer 1102 comprises a body, the body comprising a first surface 1110 and a second surface 1112. Support layer 1102 further comprises at least one through-hole 1114. Contact layer 1106 further comprises a second electrically conductive layer 1116. In some embodiments, a sidewall of through-hole 1114 comprises an electrically conductive coating 1118. In some embodiments, through-hole 1114 is filled with a conductive bonding agent 1120 in the space not occupied by electrode 1108. Electrostatic clamp 1100 further comprises a bonding agent 1122.

In some embodiments, support layer 1102 and contact layer 1106 comprise ULE materials. In some embodiments, support layer 1102 comprises the same ULE material as contact layer 1106. In some embodiments, support layer 1102 comprises a different ULE material from contact layer 1106, but the CTE of the ULE material of support layer 1102 is substantially similar to the CTE of the ULE material of contact layer 1106. The matching of CTEs improves the robustness of electrostatic clamp 1100 against failures related to thermal cycling. In some embodiments, support layer 1102 can comprise two sub-layers (not shown) of ULE material. Designing support layer 1102 as two fused sub-layers allows support layer 1102 to be fabricated as separate parts, for reasons as described earlier in reference to FIG. 8.

In some embodiments, first surface 1110 and second surface 1112 are disposed on opposite sides of the body of support layer 1102. First surface 1110 and second surface 1112 are substantially parallel to each other. Electrically conductive layer 1104 is disposed on second surface 1112 of support layer 1102. Contact layer 1106 is disposed on electrically conductive layer 1104. Second electrically conductive layer 1116 is disposed on contact layer 1106. Electrode 1108 is disposed in through-hole 1114.

In some embodiments, through-hole 1114 is configured to provide access between first surface 1110 and second surface 1112. Particularly, through-hole 1114 allows one to gain electrical access to electrically conductive layer 1104 by coming in from first surface 1110 (e.g., using electrode 1108). Similar to electrostatic clamp 800 (FIG. 8), the width of through-hole 1114 is larger at second surface 1112 than at first surface 1110. The shape of electrode 1108 conforms to the shape of through-hole 1104. However, unlike electrostatic clamp 800, contact layer 1106 is uninterrupted in the electrode region. This design is achieved, for example, by affixing electrode 1108 in through-hole 1114 before contact layer 1106 is affixed on electrically conductive layer 1104 during fabrication of electrostatic clamp 1100.

In some embodiments, electrically conductive layer 1104 and electrode 1108 are electrically coupled through electrically conductive coating 1118. In embodiments that include conductive bonding agent 1120, electrically conductive layer 1104 and electrode 1108 are electrically coupled through conductive bonding agent 1120 and/or electrically conductive coating 1118. In some embodiments, conductive bonding agent 1120 comprises a Klettwelded connection, or simply Klettweld.

In some embodiments, the portion of electrode 1108 disposed in through-hole 1114 has a width that is substantially constant. By matching a shape of electrode 1108 to a shape of through-hole 1114, a snug fit of electrode 1108 can be achieved for improved stability. For further improving stability, electrode 1108 can be affixed to support layer 1102 using bonding agent 1122.

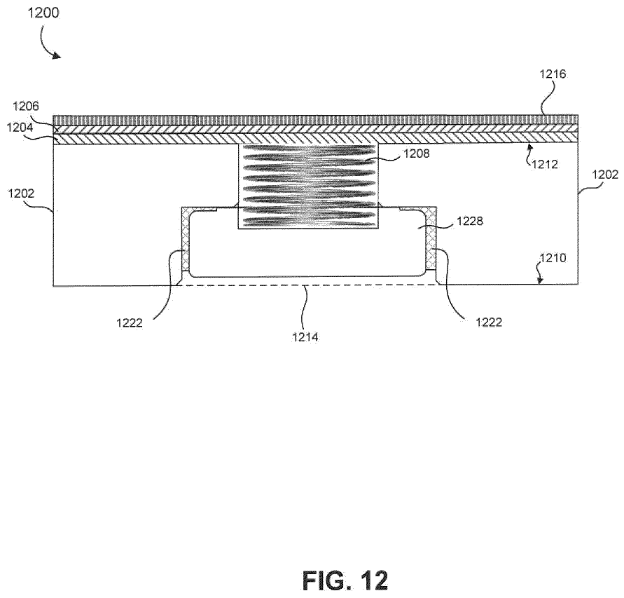

FIG. 12 shows a schematic cross-sectional view of an electrostatic clamp 1200, according to some embodiments. The region of electrostatic clamp 1200 shown in FIG. 12 is one that includes an electrode (e.g., an electrode region). It is to be appreciated that electrostatic clamp 1200 also includes a substrate region—not shown here due to limitations of cross-sectional drawings—having structures and functions as described previously for substrate region 702 (FIG. 7). In some embodiments, electrostatic clamp 1200 comprises a support layer 1202, an electrically conductive layer 1204, a contact layer 1206, and an electrode 1208. Support layer 1202 comprises a body, the body comprising a first surface 1210 and a second surface 1212. Support layer 1202 further comprises at least one through-hole 1214. Contact layer 1206 further comprises a second electrically conductive layer 1216. Electrode 1208 comprises a spring. Electrostatic clamp 1200 further comprises a bonding agent 1222 and a support piece 1228 (e.g., a spring washer).

In some embodiments, support layer 1202 and contact layer 1206 comprise ULE materials. In some embodiments, support layer 1202 comprises the same ULE material as contact layer 1206. In some embodiments, support layer 1202 comprises a different ULE material from contact layer 1206, but the CTE of the ULE material of support layer 1202 is substantially similar to the CTE of the ULE material of contact layer 1206. The matching of CTEs improves the robustness of electrostatic clamp 1200 against failures related to thermal cycling. In some embodiments, support layer 1202 can comprise two sub-layers (not shown) of ULE material. Designing support layer 1202 as two fused sub-layers allows support layer 1202 to be fabricated as separate parts, for reasons as described earlier in reference to FIG. 8.

In some embodiments, first surface 1210 and second surface 1212 are disposed on opposite sides of the body of support layer 1202. First surface 1210 and second surface 1212 are substantially parallel to each other. Electrically conductive layer 1204 is disposed on second surface 1212 of support layer 1202. Contact layer 1206 is disposed on electrically conductive layer 1204. Second electrically conductive layer 1216 is disposed on contact layer 1206. Electrode 1208 is disposed in through-hole 1214.

In some embodiments, through-hole 1214 is configured to provide access between first surface 1210 and second surface 1212. Particularly, through-hole 1214 allows one to gain electrical access to electrically conductive layer 1204 by coming in from first surface 1210 (e.g., using electrode 1208). Contact layer 1206 is uninterrupted, particularly in the electrode region.

In some embodiments, electrically conductive layer 1204 is uninterrupted, particularly in the electrode region. This configuration allows electrode 1208, being a spring, to apply a pressure on electrically conductive layer 1204 and achieve electrical coupling. The use of a spring as an electrical contact circumvents the damages caused by pressures of expanding or contracting electrodes that have rigid bodies. Electrode 1208 is supported in place using support piece 1228. Support piece 1228 comprises electrically conductive material through which a voltage source can electrically couple to electrically conductive layer 1204. In some embodiments, the width of through-hole 1214 is smaller at second surface 1212 than at first surface 1210. For improving stability, support piece 1228 can be affixed to support layer 1202 using bonding agent 1222.

In some embodiments, second electrically conductive layer 1216 is configured to provide an electrical ground.

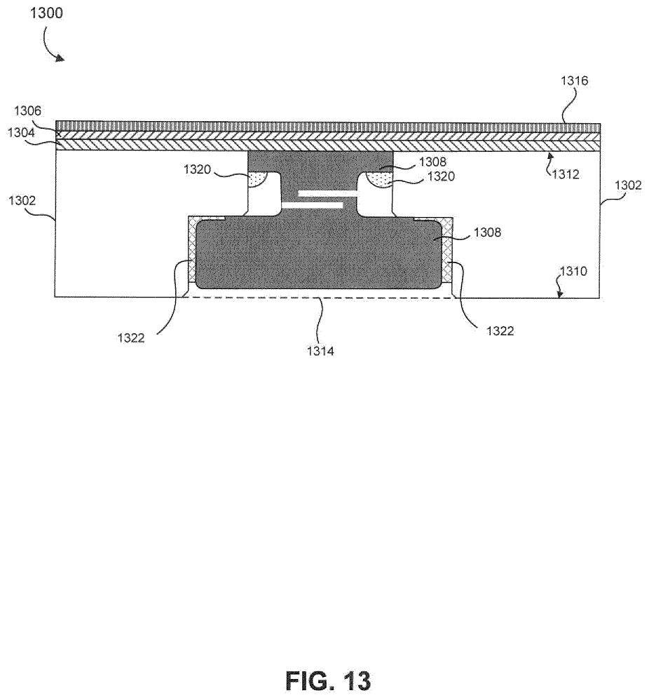

FIG. 13 shows a schematic cross-sectional view of an electrostatic clamp 1300, according to some embodiments. The region of electrostatic clamp 1300 shown in FIG. 13 is one that includes an electrode (e.g., an electrode region). It is to be appreciated that electrostatic clamp 1300 also includes a substrate region—not shown here due to limitations of cross-sectional drawings—having structures and functions as described previously for substrate region 702 (FIG. 7). In some embodiments, electrostatic clamp 1300 comprises a support layer 1302, an electrically conductive layer 1304, a contact layer 1306, and an electrode 1308. Support layer 1302 comprises a body, the body comprising a first surface 1310 and a second surface 1312. Support layer 1302 further comprises at least one through-hole 1314. Contact layer 1306 further comprises a second electrically conductive layer 1316. Electrode 1308 comprises a flexure. Electrostatic clamp 1300 further comprises a bonding agent 1320 and/or a bonding agent 1322.

In some embodiments, support layer 1302 and contact layer 1306 comprise ULE materials. In some embodiments, support layer 1302 comprises the same ULE material as contact layer 1306. In some embodiments, support layer 1302 comprises a different ULE material from contact layer 1306, but the CTE of the ULE material of support layer 1302 is substantially similar to the CTE of the ULE material of contact layer 1306. The matching of CTEs improves the robustness of electrostatic clamp 1300 against failures related to thermal cycling. In some embodiments, support layer 1302 can comprise two sub-layers (not shown) of ULE material. Designing support layer 1302 as two fused sub-layers allows support layer 1302 to be fabricated as separate parts, for reasons as described earlier in reference to FIG. 8.

In some embodiments, first surface 1310 and second surface 1312 are disposed on opposite sides of the body of support layer 1302. First surface 1310 and second surface 1312 are substantially parallel to each other. Electrically conductive layer 1304 is disposed on second surface 1312 of support layer 1302. Contact layer 1306 is disposed on electrically conductive layer 1304. Second electrically conductive layer 1316 is disposed on contact layer 1306. Electrode 1308 is disposed in through-hole 1314.

In some embodiments, through-hole 1314 is configured to provide access between first surface 1310 and second surface 1312. Particularly, through-hole 1314 allows one to gain electrical access to electrically conductive layer 1304 by coming in from first surface 1310 (e.g., using electrode 1308). Contact layer 1306 is uninterrupted, particularly in the electrode region.

In some embodiments, electrically conductive layer 1304 is uninterrupted, particularly in the electrode region. This configuration allows electrode 1308, being a flexure, to apply a pressure on electrically conductive layer 1304 and achieve electrical coupling. The use of a flexure as an electrical contact circumvents the damages caused by pressures of expanding or contracting electrodes that have rigid bodies. In embodiments that comprise bonding agent 1320, bonding agent 1320 is used to affix electrode 1308 to support layer 1302 and/or electrically conductive layer 1304. Bonding agent 1320 can be of the electrically conductive type when affixing electrode 1308 to electrically conductive layer 1304. In some embodiments, the width of through-hole 1314 is smaller at second surface 1312 than at first surface 1310. For improving stability, electrode 1308 can be affixed to support layer 1302 using bonding agent 1322.

In some embodiments, second electrically conductive layer 1316 is configured to provide an electrical ground.

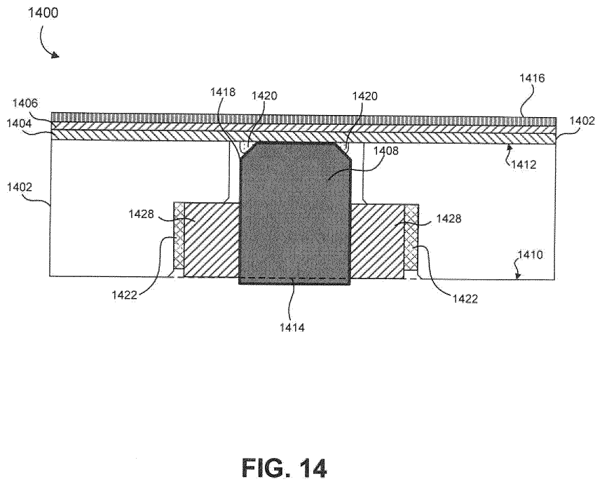

FIG. 14 shows a schematic cross-sectional view of an electrostatic clamp 1400, according to some embodiments. The region of electrostatic clamp 1400 shown in FIG. 14 is one that includes an electrode (e.g., an electrode region). It is to be appreciated that electrostatic clamp 1400 also includes a substrate region—not shown here due to limitations of cross-sectional drawings—having structures and functions as described previously for substrate region 702 (FIG. 7). In some embodiments, electrostatic clamp 1400 comprises a support layer 1402, an electrically conductive layer 1404, a contact layer 1406, and an electrode 1408. Support layer 1402 comprises a body, the body comprising a first surface 1410 and a second surface 1412. Support layer 1402 further comprises at least one through-hole 1414. Contact layer 1406 further comprises a second electrically conductive layer 1416. Electrode 1408 comprises an electrically conductive coating 1418. Electrostatic clamp 1400 further comprises a conductive bonding agent 1420, a bonding agent 1422, and a support piece 1428 (e.g., an alignment ring).

In some embodiments, support layer 1402, contact layer 1406, and electrode 1408 comprise ULE materials. In some embodiments, support layer 1402, contact layer 1406, and electrode 1408 comprise the same ULE material. In some embodiments, support layer 1402, contact layer 1406, and electrode 1408 comprise distinct ULE materials, but the CTE of the distinct ULE materials are substantially similar to each other. The matching of CTEs improves the robustness of electrostatic clamp 1400 against failures related to thermal cycling. In some embodiments, support layer 1402 can comprise two sub-layers (not shown) of ULE material. Designing support layer 1402 as two fused sub-layers allows support layer 1402 to be fabricated as separate parts, for reasons as described earlier in reference to FIG. 8.

In some embodiments, first surface 1410 and second surface 1412 are disposed on opposite sides of the body of support layer 1402. First surface 1410 and second surface 1412 are substantially parallel to each other. Electrically conductive layer 1404 is disposed on second surface 1412 of support layer 1402. Contact layer 1406 is disposed on electrically conductive layer 1404. Second electrically conductive layer 1416 is disposed on contact layer 1406. Electrode 1408 is disposed in through-hole 1414.

In some embodiments, through-hole 1414 is configured to provide access between first surface 1410 and second surface 1412. Particularly, through-hole 1414 allows one to gain electrical access to electrically conductive layer 1404 by coming in from first surface 1410 (e.g., using electrode 1408). Contact layer 1406 is uninterrupted, particularly in the electrode region.

In some embodiments, electrically conductive layer 1404 is uninterrupted, particularly in the electrode region. In this configuration, the damaging pressure impinging on electrically conductive layer 1404 and contact layer 1406 is substantially reduced because electrode 1408 has a CTE that is similar to those of support layer 1402 and contact layer 1406. Electrically conductive coating 1418 on electrode 1408 provides the electrical connection between electrically conductive layer 1404 and an external power supply (e.g., voltage source). Conductive bonding agent 1420 is used to affix electrode 1408 to electrically conductive layer 1404. In some embodiments, the width of through-hole 1414 is smaller at second surface 1412 than at first surface 1410. To improve stability, in some embodiments, support piece 1428 supports electrode 1408 in through-hole 1414. Support piece 1428 can have the same materials configuration as electrode 1408 (e.g., ULE body with conductive coating) or be purely of a ULE material or an electrically conductive material. By matching a shape of the electrode/alignment ring assembly to a shape of through-hole 1414, a snug fit of electrode 1408 can be achieved for improved stability. For further improving stability, support piece 1428 can be affixed to support layer 1402 using bonding agent 1422.

In some embodiments, second electrically conductive layer 1416 is configured to provide an electrical ground.

The embodiments may further be described using the following clauses:

1. An electrostatic clamp for supporting a substrate, the electrostatic clamp comprising:

a substrate region and an electrode region at an edge of the substrate region;

a support layer comprising a body, the body comprising:
first and second surfaces disposed on opposite sides of the body, wherein the first surface is substantially parallel with the second surface;
at least one through-hole in the electrode region, the through-hole configured to provide access between the first and second surfaces, wherein a width of the through-hole is smaller at the second surface than at the first surface;

an electrically conductive layer disposed on the second surface of the support layer;

a contact layer disposed on the electrically conductive layer, wherein the contact layer is uninterrupted in the electrode region and comprises burls in the substrate region, and wherein the burls are configured to contact the substrate when the electrostatic clamp is supporting the substrate; and

an electrode disposed in the through-hole and electrically coupled to the electrically conductive layer.

2. The electrostatic clamp of clause 1, wherein a sidewall of the through-hole comprises an electrically conductive coating and the electrode is electrically coupled to the electrically conductive layer through the electrically conductive coating.
3. The electrostatic clamp of clause 1, wherein the through-hole is filled with electrically conductive material and the electrode is electrically coupled to the electrically conductive layer through the electrically conductive material.
4. The electrostatic clamp of clause 1, wherein the electrode disposed in the through hole has a width that is smaller away from the first surface and toward the second surface than at the first surface.
5. The electrostatic clamp of clause 1, wherein the electrode disposed in the through hole has a width that is substantially constant.
6. The electrostatic clamp of clause 1, wherein the electrode comprises an electrically conductive spring.
7. The electrostatic clamp of clause 1, wherein the electrode comprises an electrically conductive flexure.
8. An electrostatic clamp for supporting a substrate, the electrostatic clamp comprising:

a substrate region and an electrode region at an edge of the substrate region;

a support layer comprising a body, the body comprising:
first and second surfaces disposed on opposite sides of the body, wherein the first surface is substantially parallel with the second surface;
at least one through-hole in the electrode region, the through-hole configured to provide access between the first and second surfaces, wherein a width of the through-hole is larger at the second surface than at the first surface;

an electrically conductive layer disposed on the second surface of the support layer; a contact layer disposed on the electrically conductive layer, wherein the contact layer is uninterrupted in the electrode region and comprises burls in the substrate region, and wherein the burls are configured to contact the substrate when the electrostatic clamp is supporting the substrate; and

an electrode disposed in the through-hole and electrically coupled to the electrically conductive layer.

9. The electrostatic clamp of clause 8, wherein a sidewall of the through-hole comprises an electrically conductive coating and the electrode is electrically coupled to the electrically conductive layer through the electrically conductive coating.
10. The electrostatic clamp of clause 8, wherein the through-hole is filled with electrically conductive material and the electrode is electrically coupled to the electrically conductive layer through the electrically conductive material.
11. The electrostatic clamp of clause 8, wherein the electrode comprises a Klettwelded connection and the electrode is electrically coupled to the electrically conductive layer through the Klettwelded connection.
12. The electrostatic clamp of clause 8, wherein the electrode disposed in the through hole has a width that is larger away from the first surface and toward the second surface than at the first surface.
13. The electrostatic clamp of clause 8, wherein the electrode comprises an electrically conductive spring.
14. The electrostatic clamp of clause 8, wherein the electrode comprises an electrically conductive flexure.
15. An electrostatic clamp for supporting a substrate, the electrostatic clamp comprising:

a substrate region and an electrode region at an edge of the substrate region;

a support layer comprising a body, the body comprising:
first and second surfaces disposed on opposite sides of the body, wherein the first surface is substantially parallel with the second surface;
at least one through-hole in the electrode region, the through-hole configured to provide access between the first and second surfaces;

an electrically conductive layer disposed on the second surface of the support layer;

a contact layer disposed on the electrically conductive layer, wherein the contact layer is uninterrupted in the electrode region and comprises burls in the substrate region, and wherein the burls are configured to contact the substrate; and

an electrode disposed in the through hole and electrically coupled to the electrically conductive layer, the electrode comprising an electrically conductive spring.

16. An electrostatic clamp for supporting a substrate, the electrostatic clamp comprising:

a substrate region and an electrode region at an edge of the substrate region;

a support layer comprising a body, the body comprising:
first and second surfaces disposed on opposite sides of the body, wherein the first surface is substantially parallel with the second surface;
at least one through-hole in the electrode region, the through-hole configured to provide access between the first and second surfaces;

an electrically conductive layer disposed on the second surface of the support layer;

a contact layer disposed on the electrically conductive layer, wherein the contact layer is uninterrupted in the electrode region and comprises burls in the substrate region, and wherein the burls are configured to contact the substrate when the electrostatic clamp is supporting the substrate; and

an electrode disposed in the through hole and electrically coupled to the electrically conductive layer, the electrode comprising an electrically conductive flexure.

Embodiments described herein provide clamp structures and methods for reducing defectivity related issues on the clamp surface, reducing additional assembly steps (glass cap), and improving clean-ability of parts by reducing regions where particles can be trapped (flat surfaces).

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin film magnetic heads, etc.

Although specific reference may be made in this text to embodiments of the disclosure in the context of a lithographic apparatus, embodiments of the disclosure may be used in other apparatuses. Embodiments of the disclosure may form part of a mask inspection apparatus, a metrology apparatus, or any apparatus that measures or processes an object such as a wafer (or other substrate) or mask (or other patterning device). These apparatuses may be generally referred to as lithographic tools. Such lithographic tools may use vacuum conditions or ambient (non-vacuum) conditions.

Although specific reference may have been made above to the use of embodiments of the disclosure in the context of optical lithography, it will be appreciated that the disclosure, where the context allows, is not limited to optical lithography and may be used in other applications, for example imprint lithography.

It is to be understood that the phraseology or terminology herein is for the purpose of description and not of limitation, such that the terminology or phraseology of the present specification is to be interpreted by those skilled in relevant art(s) in light of the teachings herein.

The above examples are illustrative, but not limiting, of the embodiments of this disclosure. Other suitable modifications and adaptations of the variety of conditions and parameters normally encountered in the field, and which would be apparent to those skilled in the relevant art(s), are within the spirit and scope of the disclosure.

While specific embodiments of the disclosure have been described above, it will be appreciated that the disclosure may be practiced otherwise than as described. The descriptions above are intended to be illustrative, not limiting. Thus it will be apparent to one skilled in the art that modifications may be made to the disclosure as described without departing from the scope of the claims set out below.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein.

The breadth and scope of the present invention should not be limited by any of the above-described exemplary embodiments, but should be defined only in accordance with the following claims and their equivalents.

1.-16. (canceled)

17. An electrostatic clamp for supporting a substrate, the electrostatic clamp comprising:
a substrate region and an electrode region at an edge of the substrate region;
a support layer comprising a body, the body comprising:
first and second surfaces disposed on opposite sides of the body, wherein the first surface is substantially parallel with the second surface;
at least one through-hole in the electrode region, the through-hole configured to provide access between the first and second surfaces, wherein a width of the through-hole is smaller at the second surface than at the first surface;
an electrically conductive layer disposed on the second surface of the support layer;
a contact layer disposed on the electrically conductive layer, wherein the contact layer is uninterrupted in the electrode region and comprises burls in the substrate region, and wherein the burls are configured to contact the substrate when the electrostatic clamp is supporting the substrate; and
an electrode disposed in the through-hole and electrically coupled to the electrically conductive layer.

18. The electrostatic clamp of claim 17, wherein a sidewall of the through-hole comprises an electrically conductive coating, and the electrode is electrically coupled to the electrically conductive layer through the electrically conductive coating.

19. The electrostatic clamp of claim 17, wherein the through-hole is filled with an electrically conductive material, and the electrode is electrically coupled to the electrically conductive layer through the electrically conductive material.

20. The electrostatic clamp of claim 17, wherein the electrode disposed in the through hole, has a width that is smaller away from the first surface and toward the second surface than at the first surface.

21. The electrostatic clamp of claim 17, wherein the electrode disposed in the through hole, has a width that is substantially constant.

22. The electrostatic clamp of claim 17, wherein the electrode comprises an electrically conductive spring.

23. The electrostatic clamp of claim 17, wherein the electrode comprises an electrically conductive flexure.

24. An electrostatic clamp for supporting a substrate, the electrostatic clamp comprising:
a substrate region and an electrode region at an edge of the substrate region;
a support layer comprising a body, the body comprising:
first and second surfaces disposed on opposite sides of the body, wherein the first surface is substantially parallel with the second surface;
at least one through-hole in the electrode region, the through-hole configured to provide access between the first and second surfaces, wherein a width of the through-hole is larger at the second surface than at the first surface;
an electrically conductive layer disposed on the second surface of the support layer;
a contact layer disposed on the electrically conductive layer, wherein the contact layer is uninterrupted in the electrode region and comprises burls in the substrate region, and wherein the burls are configured to contact the substrate when the electrostatic clamp is supporting the substrate; and
an electrode disposed in the through-hole and electrically coupled to the electrically conductive layer.

25. The electrostatic clamp of claim 24, wherein a sidewall of the through-hole comprises an electrically conductive coating, and the electrode is electrically coupled to the electrically conductive layer through the electrically conductive coating.

26. The electrostatic clamp of claim 24, wherein the through-hole is filled with the electrically conductive material, and the electrode is electrically coupled to the electrically conductive layer through the electrically conductive material.

27. The electrostatic clamp of claim 24, wherein the electrode comprises a Klettwelded connection, and the electrode is electrically coupled to the electrically conductive layer through the Klettwelded connection.

28. The electrostatic clamp of claim 24, wherein the electrode disposed in the through hole, has a width that is larger away from the first surface and toward the second surface than at the first surface.

29. The electrostatic clamp of claim 24, wherein the electrode comprises an electrically conductive spring.

30. The electrostatic clamp of claim 24, wherein the electrode comprises an electrically conductive flexure.

31. An electrostatic clamp for supporting a substrate, the electrostatic clamp comprising:
a substrate region and an electrode region at an edge of the substrate region;
a support layer comprising a body, the body comprising:
first and second surfaces disposed on opposite sides of the body, wherein the first surface is substantially parallel with the second surface;
at least one through-hole in the electrode region, the through-hole configured to provide access between the first and second surfaces;
an electrically conductive layer disposed on the second surface of the support layer;
a contact layer disposed on the electrically conductive layer, wherein the contact layer is uninterrupted in the electrode region and comprises burls in the substrate region, and wherein the burls are configured to contact the substrate; and
an electrode disposed in the through hole and electrically coupled to the electrically conductive layer, the electrode comprising an electrically conductive spring.

32. An electrostatic clamp for supporting a substrate, the electrostatic clamp comprising:
a substrate region and an electrode region at an edge of the substrate region;
a support layer comprising a body, the body comprising:
first and second surfaces disposed on opposite sides of the body, wherein the first surface is substantially parallel with the second surface;
at least one through-hole in the electrode region, the through-hole configured to provide access between the first and second surfaces;
an electrically conductive layer disposed on the second surface of the support layer;
a contact layer disposed on the electrically conductive layer, wherein the contact layer is uninterrupted in the electrode region and comprises burls in the substrate region, and wherein the burls are configured to contact the substrate when the electrostatic clamp is supporting the substrate; and
an electrode disposed in the through hole and electrically coupled to the electrically conductive layer, the electrode comprising an electrically conductive flexure.
